(19) United States
(12) Patent Application Publication
(10) Pub. No.: US 2025/0034696 A1
(43) Pub. Date: Jan. 30, 2025

(54) Target material structure and manufacturing method thereof

(71) Applicant: United Semiconductor (Xiamen) Co., Ltd., Xiamen (CN)

(72) Inventors: Yongbo Xu, Xia Men (CN); Shouguo Zhang, Singapore (SG); Wen Yi Tan, Xiamen (CN); Ching-Shu Lo, Singapore (SG)

(73) Assignee: United Semiconductor (Xiamen) Co., Ltd., Xiamen (CN)

(21) Appl. No.: 18/235,889

(22) Filed: Aug. 21, 2023

(30) Foreign Application Priority Data
Jul. 24, 2023 (CN) 202310909277.5

(51) Int. Cl. C23C 14/34; C23C 14/14

(52) U.S. Cl. CPC C23C 14/3414; C23C 14/14

(57) ABSTRACT

The invention provides a target material structure suitable for semiconductor manufacturing process, which comprises an alloy made of a first metal and a second metal, the target material structure comprises an upper section and a lower section, the atomic ratio of the first metal to the second metal in the lower section is different from the atomic ratio of the first metal to the second metal in the upper section.

### BACKGROUND OF THE INVENTION

### 1. Field of the Invention

The invention relates to the field of semiconductor process, in particular to a target material structure suitable for physical vapor deposition process and a manufacturing method thereof.

### 2. Description of the Prior Art

Vapor deposition is one of the common process steps of semiconductor, which can deposit various required material layers on the substrate located in the chamber.

Alloys are often used as deposition material layers in general semiconductor processes, such as the work function material layer in the gate. At this time, the target material structure made of alloy will be placed in the chamber. When the physical vapor deposition is carried out, inert gas ions bombard the target material structure, which will disperse the material particles in the air in the chamber and plate the material layer on the required substrate.

### SUMMARY OF THE INVENTION

The invention provides a target material structure suitable for semiconductor manufacturing process, which comprises a target material structure, which is an alloy made of a first metal and a second metal, wherein the target material structure comprises an upper section and a lower section, wherein the atomic ratio of the first metal to the second metal in the lower section is different from the atomic ratio of the first metal to the second metal in the upper section.

The invention also provides a method for manufacturing a target material structure suitable for a semiconductor process, which comprises forming a target material structure made of an alloy of a first metal and a second metal, wherein the target material structure comprises an upper section and a lower section, wherein the atomic ratio of the first metal to the second metal in the lower section is different from that in the upper section.

The invention provides a target material structure for physical vapor deposition (PVD) process in semiconductor process, wherein the target material structure contains two metals (such as titanium and aluminum), and the ratio of the two metals in the lower section of the target material structure is different from that in the upper section of the target material structure. The applicant found that because of the different atomic weights of metals, one of the metals (such as aluminum) will be easily bombarded and scattered, and when the target material structure is used for a long time, the metal ratio of the deposited alloy layer will be affected. The invention is characterized in that in the designed target material structure, the proportional relationship between the two metals is adjusted with the height, so that the problem that one metal of the target material structure is easily bombarded and scattered due to the atomic weight difference, thus affecting the ratio of the deposited alloy layer can be corrected, and further improving the process quality.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram showing the proportional relationship between aluminum and titanium in an aluminum-titanium alloy layer deposited by using a conventional aluminum-titanium alloy target material structure for a period of time.

FIG. 2 is a schematic diagram of a target material structure according to a first embodiment of the present invention.

FIG. 3 is a schematic diagram showing the proportional relationship between aluminum and titanium in the aluminum-titanium alloy layer deposited by using the aluminum-titanium alloy target material structure of the present invention for a period of time.

FIG. 4 is a schematic diagram of a target material structure according to a second embodiment of the present invention.

### DETAILED DESCRIPTION

To provide a better understanding of the present invention to users skilled in the technology of the present invention, preferred embodiments are detailed as follows. The preferred embodiments of the present invention are illustrated in the accompanying drawings with numbered elements to clarify the contents and the effects to be achieved.

Please note that the figures are only for illustration and the figures may not be to scale. The scale may be further modified according to different design considerations. When referring to the words “up” or “down” that describe the relationship between components in the text, it is well known in the art and should be clearly understood that these words refer to relative positions that can be inverted to obtain a similar structure, and these structures should therefore not be precluded from the scope of the claims in the present invention.

In the conventional step, target material structure and vapor deposition are used to deposit the required metal layer, for example, aluminum-titanium alloy (AlTi) target material structure is used to deposit the work function layer in the semiconductor gate.

The applicant found that the aluminum-titanium alloy target material structure in the conventional step has some disadvantages. Firstly, the atomic weight of aluminum (27) is smaller than that of titanium (48), which leads to the light weight of aluminum atoms. When bombarding the target material structure with inert gas ions (such as argon ions) in the PVD step, aluminum atoms will be more easily knocked out and dispersed into the chamber and deposited as aluminum-titanium alloy than titanium atoms, which will become more obvious as the target material structure is used for a long time. Please refer to FIG. 1, which is a schematic diagram showing the ratio of aluminum to titanium in an aluminum-titanium alloy layer deposited by using a conventional aluminum-titanium alloy target material structure for a period of time. As shown in FIG. 1, the horizontal axis is time, and the vertical axis is the measured aluminum content ratio in the aluminum-titanium alloy. Here, the numerical value of the vertical axis varies between 1.7 and 2. This numerical value is calculated by measuring the atomic number of aluminum and titanium per unit area in the aluminum-titanium alloy layer deposited on the wafer with a metrology tool called HKXPS, and then dividing them to calculate the ratio. It can be found that the ratio of aluminum in the aluminum-titanium alloy layer increases gradually with time, and it is necessary to replace the target material structure at this time to restore the atomic ratio of aluminum to titanium to normal (as shown in FIG. 1, the low point formed by sudden drop in each rising process is the time to replace the target material structure). In other words, the applicant measured the deposited aluminum-titanium alloy layer, and found that with the use of the target material structure, the aluminum content in the aluminum-titanium alloy layer gradually increased until the aluminum content in the aluminum-titanium alloy layer exceeded a prescribed upper limit, which meant that the formed aluminum-titanium alloy layer did not meet the specifications, so it was necessary to replace the new target material structure before the target material structure was used up, which also caused waste of materials.

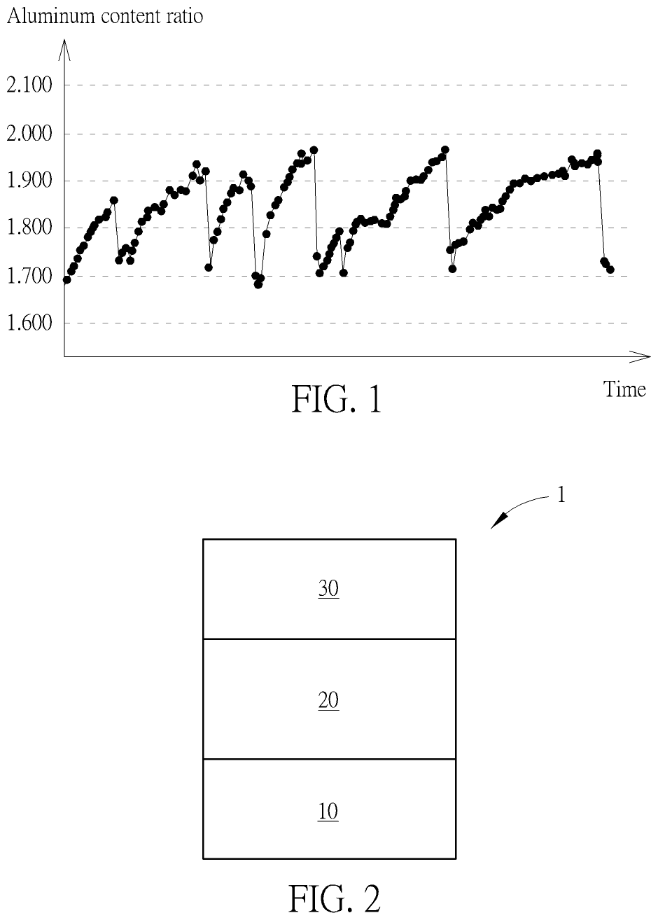

Please refer to FIG. 2, which shows the schematic diagram of the target material structure according to the first embodiment of the present invention. As shown in FIG. 2, the target material structure 1 provided by the present invention is a target material structure suitable for semiconductor physical vapor deposition (PVD), which contains at least two metals. In this invention, aluminum and titanium are taken as examples, that is to say, the main material of the target material structure 1 is aluminum-titanium alloy (AlTi). After the physical vapor deposition step, an aluminum-titanium alloy layer can also be formed on the target material structure substrate, which can be used as a work function layer in semiconductor manufacturing.

The target material structure 1 of the present invention includes a plurality of different sections, such as a lower section 10, a middle section 20 and an upper section 30. Among them, the ratios of aluminum and titanium contained in the lower section 10, the middle section 20 and the upper section 30 are different. For example, in the lower section 10, the ratios of aluminum and titanium are about 50:50, while in the middle section 20, the ratios of aluminum and titanium are about 30:70 (that is, the ratios of aluminum decrease), and in the upper section 30, the ratios of aluminum and titanium are about 20:80 (that is, the ratio of aluminum decreases again), but the above proportional relationship is only one example of the present invention, and the present invention is not limited to this. It only needs to be satisfied that the atomic proportional relationship between the two metals is different from each other in different sections, which should belong to the scope of the invention.

When the target material structure 1 is used for physical vapor deposition, the target material structure will be consumed from the lower section 10, and then the middle section 20 and the upper section 30 will be gradually consumed in sequence. As observed in FIG. 1 above, aluminum is easily bombarded in the physical vapor deposition step, drifted into the air, and deposited as an aluminum-titanium alloy layer, resulting in a gradual increase in aluminum content in the aluminum-titanium alloy layer. Therefore, the aluminum content in the target material structure 1 designed by the invention gradually decreases with the use time, so the above-mentioned problem of gradual increase in aluminum content can be offset or compensated.

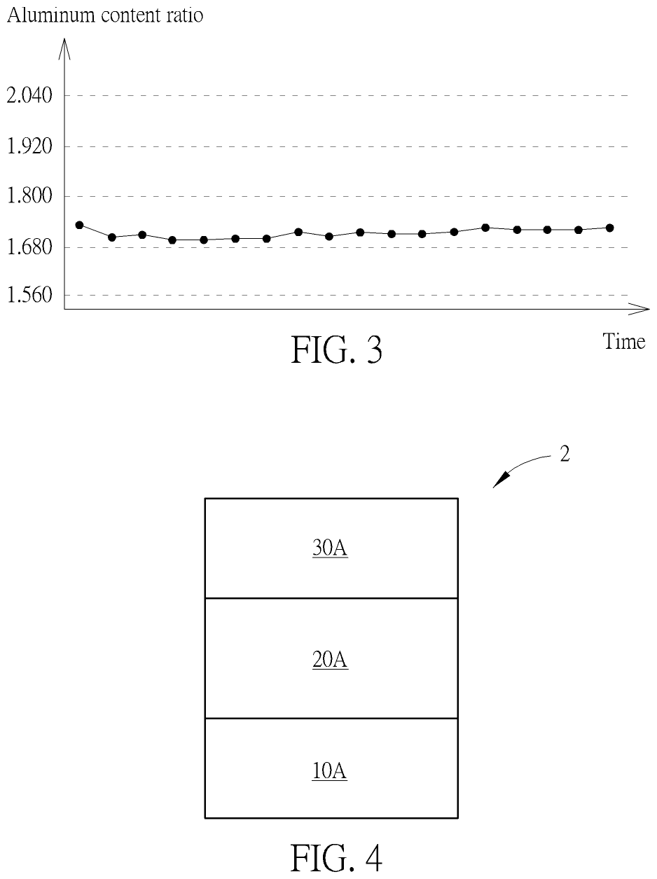

According to the actual observation of the applicant, the target material structure 1 provided by the invention does have the problem of improving the gradual increase of aluminum content in the aluminum-titanium alloy layer shown in FIG. 1. FIG. 3 is a schematic diagram showing the proportional relationship between aluminum and titanium in the aluminum-titanium alloy layer deposited by using the aluminum-titanium alloy target material structure of the present invention for a period of time. As shown in FIG. 3, the aluminum content in the aluminum-titanium alloy layer does not increase obviously, so the process can be stabilized, and it is not necessary to replace the target material structure in advance before the target material structure is consumed, which also saves the cost.

In practice, the aluminum-titanium alloy target material structure 1 of the present invention can be made by blending and pressing aluminum powder and titanium powder. For example, aluminum powder and titanium powder with roughly the same ratio can be blended to form aluminum-titanium mixed powder with the ratio of aluminum to titanium of about 50:50, and then the aluminum-titanium mixed powder can be pressed to form an aluminum-titanium alloy layer constituting the lower section 10. Then, the above steps can be repeated, and other multilayer aluminum-titanium alloy layers can be formed and stacked on them in the same way. It should be noted that with the elevation of aluminum-titanium alloy layer, that is, gradually from the lower section 10 to the middle section 20 or the upper section 30, the ratio of mixed aluminum powder to titanium powder should be adjusted, that is, the ratio of aluminum powder should be gradually reduced, so that the target material structure 1 as shown in FIG. 2 can be manufactured.

Please refer to FIG. 4, which shows a schematic diagram of the target material structure according to the second embodiment of the present invention. As shown in FIG. 4, the target material structure 2 of this embodiment is similar to the target material structure 1 shown in FIG. 2 above, but the difference is that the aluminum ratio of the target material structure 2 in this embodiment decreases in a gradient manner with the increase of height. In more detail, the target material structure 2 includes a lower section 10A, a middle section 20A and an upper section 30A, and the ratios of aluminum to titanium in different sections are different. In addition, in the same section (taking the lower section 10A as an example), the ratio of aluminum to titanium gradually and continuously decreases with the height increase. Therefore, in this embodiment, near the boundaries between different sections, the change of aluminum ratio will be relatively smooth, and the aluminum ratio will not suddenly drop significantly as shown in the embodiment of FIG. 2. The manufacturing method of the target material structure 2 in this embodiment is also similar to the above description. The target material structure 2 shown in FIG. 4 can be formed by repeatedly mixing aluminum powder and titanium powder in different ratios and pressing them, and the other features are the same as those described above, so they are not repeated here.

In addition, although the target material structure in the above embodiment is divided into three sections, namely, the upper section, the middle section and the lower section, the number of sections is not limited in the present invention, that is, more or less sections may be formed in other embodiments, which is also within the scope of the present invention.

In addition, although aluminum-titanium alloy is taken as an example of the target material structure in this embodiment, the invention can also be applied to other kinds of alloy target material structures, such as tellurium-antimony, chromium-titanium, silicon-titanium, molybdenum-chromium, chromium-nickel, vanadium-nickel, copper-nickel, tungsten-chromium, vanadium-chromium, terbium iron cobalt and other alloy target material structures, so long as the atomic weights of two or three metals in the alloy are different, they can all be applied to the scope of the invention.

Based on the above description and drawings, a target material structure 1 suitable for semiconductor manufacturing process of the present invention comprises a target material structure, wherein the target material structure 1 is an alloy made of a first metal (such as aluminum) and a second metal (such as titanium), wherein the target material structure 1 comprises an upper section 30 and a lower section 10, wherein the atomic ratio of the first metal to the second metal in the lower section 10 is different from the atomic ratio of the first metal to the second metal in the upper section 30.

In some embodiments of the present invention, the first metal comprises aluminum and the second metal comprises titanium.

In some embodiments of the present invention, the atomic ratio of the first metal to the second metal is 1:1 in the lower section 10.

In some embodiments of the present invention, the atomic percentage value of the first metal and the second metal is less than 0.3 in the upper section 30 (for example, the ratio of aluminum to titanium is 20:80, so 20/80<0.3).

In some embodiments of the present invention, the target material structure further comprises a middle section 20, which is located between the upper section 30 and the lower section 10.

In some embodiments of the present invention, in the target material structure 2, the atomic percentage values of the first metal and the second metal decrease gradually from the lower section 10A, the middle section 20A to the upper section 30A (as shown in the embodiment of FIG. 4).

In some embodiments of the present invention, in which the target material structure 1 is in any one of the lower section 10, the middle section 20 or the upper section 30, the atomic percentage values of the first metal and the second metal are fixed (as shown in the embodiment of FIG. 2).

In some embodiments of the present invention, the target material structure is used in a physical vapor deposition (PVD) machine.

The invention also provides a method for manufacturing a target material structure suitable for a semiconductor process, which comprises forming a target material structure 1, wherein the target material structure 1 is an alloy made of a first metal (such as aluminum) and a second metal (such as titanium), wherein the target material structure comprises an upper section 30 and a lower section 10, wherein the atomic ratio of the first metal to the second metal in the lower section 10 is different from the atomic ratio of the first metal to the second metal in the upper section 30.

In some embodiments of the present invention, the method of forming the target material structure further comprises providing a first metal powder (such as aluminum powder) and a second metal powder (such as titanium powder), mixing them with each other in a first ratio (for example, about 50:50), performing a pressing step, making the first metal powder and the second metal powder into a first alloy layer, and providing the first metal powder and the second metal powder again and mixing them with each other in a second ratio. Wherein the second ratio is different from the first ratio (for example, the ratio of 30:70 or 20:80), another pressing step is performed to make the first metal powder and the second metal powder into a second alloy layer and stack them on the first alloy layer.

In some embodiments of the present invention, the percentage of the first metal in the total volume (for example, 50%) is greater than the percentage of the first metal in the total volume (for example, 20%) in the second ratio.

The invention provides a target material structure for physical vapor deposition (PVD) process in semiconductor process, wherein the target material structure contains two metals (such as titanium and aluminum), and the ratio of the two metals in the lower section of the target material structure is different from that in the upper section of the target material structure. The applicant found that because of the different atomic weights of metals, one of the metals (such as aluminum) will be easily bombarded and scattered, and when the target material structure is used for a long time, the metal ratio of the deposited alloy layer will be affected. The invention is characterized in that in the designed target material structure, the proportional relationship between the two metals is adjusted with the height, so that the problem that one metal of the target material structure is easily bombarded and scattered due to the atomic weight difference, thus affecting the ratio of the deposited alloy layer can be corrected, and further improving the process quality.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A target material structure suitable for semiconductor manufacturing, comprising:
a target material structure, which is an alloy made of a first metal and a second metal, wherein the target material structure comprises an upper section and a lower section, wherein the atomic ratio of the first metal to the second metal in the lower section is different from the atomic ratio of the first metal to the second metal in the upper section.

2. The target material structure according to claim 1, wherein the first metal comprises aluminum and the second metal comprises titanium.

3. The target material structure according to claim 1, wherein the atomic ratio of the first metal to the second metal is 1:1 in the lower section.

4. The target material structure according to claim 1, wherein the atomic percentage value of the first metal and the second metal is less than 0.3 in the upper section.

5. The target material structure according to claim 1, further comprising a middle section between the upper section and the lower section.

6. The target material structure according to claim 5, wherein the atomic percentage values of the first metal and the second metal decrease gradually from the lower section, the middle section to the upper section.

7. The target material structure according to claim 5, wherein the atomic percentage values of the first metal and the second metal are fixed in any section of the lower section, the middle section or the upper section.

8. The target material structure according to claim 1, wherein the target material structure is used in a physical vapor deposition (PVD) machine.

9. A method for manufacturing a target material structure suitable for a semiconductor process, comprising:
forming a target material structure which is an alloy made of a first metal and a second metal, wherein the target material structure comprises an upper section and a lower section, wherein the atomic ratio of the first metal to the second metal in the lower section is different from the atomic ratio of the first metal to the second metal in the upper section.

10. The manufacturing method of the target material structure according to claim 9, wherein the first metal comprises aluminum and the second metal comprises titanium.

11. The manufacturing method of the target material structure according to claim 9, wherein the atomic ratio of the first metal to the second metal is 1:1 in the lower section.

12. The manufacturing method of the target material structure according to claim 9, wherein the atomic percentage value of the first metal and the second metal is less than 0.3 in the upper section.

13. The manufacturing method of the target material structure according to claim 9, wherein the target material structure further comprises a middle section between the upper section and the lower section.

14. The manufacturing method of the target material structure according to claim 13, wherein the atomic percentage values of the first metal and the second metal decrease gradually from the lower section, the middle section to the upper section.

15. The manufacturing method of the target material structure according to claim 13, wherein the atomic percentage values of the first metal and the second metal are fixed in any section of the lower section, the middle section or the upper section.

16. The manufacturing method of the target material structure according to claim 9, wherein the target material structure is used in a physical vapor deposition (PVD) machine.

17. The method for manufacturing the target material structure according to claim 9, wherein the method for forming the target material structure further comprises:
providing a first metal powder and a second metal powder which are mixed with each other in a first ratio;
performing a pressing step to make the first metal powder and the second metal powder into a first alloy layer;
providing the first metal powder and the second metal powder again, and mixing with each other in a second ratio, wherein the second ratio is different from the first ratio;
performing another pressing step to make the first metal powder and the second metal powder into a second alloy layer and stack the second alloy layer on the first alloy layer.

18. The method for manufacturing a target material structure according to claim 17, wherein the percentage of the first metal in the total volume in the first ratio is greater than the percentage of the first metal in the total volume in the second ratio.
